(19) United States
(12) Patent Application Publication
(10) Pub. No.: US 2021/0364585 A1
(43) Pub. Date: Nov. 25, 2021

(54) MAGNETIC RESONANCE IMAGING RADIO-FREQUENCY COIL ASSEMBLY WITH HIGH TIME-DOMAIN SIGNAL STABILITY

(71) Applicant: ZHEJIANG UNIVERSITY, Hangzhou City (CN)

(72) Inventors: Xiaotong Zhang, Hangzhou City (CN); Yang Gao, Hangzhou City (CN)

(21) Appl. No.: 17/395,406

(22) Filed: Aug. 5, 2021

Related U.S. Application Data
(63) Continuation of application No. PCT/CN2020/113869, filed on Sep. 8, 2020.

(30) Foreign Application Priority Data
Dec. 2, 2019 (CN) 201911213882.9

(51) Int. Cl. G01R 33/3415; G01R 33/36; G01R 33/48; G01R 33/38

(52) U.S. Cl. CPC G01R 33/3415; G01R 33/3621; G01R 33/3642; G01R 33/38; G01R 33/4806

(57) ABSTRACT

Disclosed is a magnetic resonance imaging radio-frequency coil assembly with high time-domain signal stability, mainly including a radio-frequency transmitting coil unit, a plurality of radio-frequency receiving coil units, and a housing structure. A plane area of the radio-frequency transmitting coil unit is larger than a sum of layout plane areas of all of the plurality of radio-frequency receiving coil units. The plurality of radio-frequency receiving coil units are arranged at an internal side of the radio-frequency transmitting coil unit. An overall size of an array formed by the plurality of radio-frequency receiving coil units is larger than a size of an imaging region. A circumference of each radio-frequency receiving coil unit is less than one tenth of a wavelength of a vacuum electromagnetic wave. Thermal noise from the load accounts for a small proportion in the radio-frequency receiving coil units.

### TECHNICAL FIELD

The present disclosure relates to the field of magnetic resonance imaging systems, and more particularly, to a magnetic resonance imaging radio-frequency coil assembly with high time-domain signal stability.

### BACKGROUND

The basic principle of magnetic resonance imaging comes from the discovery of American scholars Bloch and Purcell in 1946. Under an external magnetic field, precession angles of some spin protons (including hydrogen protons in human body) precessing around a main magnetic field (external magnetic field) are increased under the action of a short radio-frequency wave; after the radio-frequency wave stops, the protons gradually revert back to their original state, simultaneously emitting a radio frequency signal at the same frequency as an excitation wave. Such a physical phenomenon is referred to as magnetic resonance imaging. The magnetic resonance imaging technology is to use this principle to attach a pulsed gradient magnetic field to the main magnetic field to selectively excite nuclei in a human body at a desired position, then receive magnetic resonance signals generated by the nuclei, and finally perform Fourier transform in a computer to perform frequency coding and phase coding of these signals, so as to establish a complete magnetic resonance image.

A magnetic resonance imaging device includes a radio-frequency transmitting coil and a radio-frequency receiving coil. The radio-frequency transmitting coil is used for generating a radio-frequency pulse that excites protons, and the radio-frequency receiving coil is used for receiving magnetic resonance signals generated by nuclei. In a magnetic resonance imaging system, key factors for obtaining high quality-images are good uniformity of a magnetic field generated by the radio-frequency transmitting coil, high transmission efficiency, and a high signal-to-noise ratio (SNR) of the signals received by the radio-frequency receiving coil. For a magnetic resonance system with low main magnetic field intensity (no higher than 3 tesla), the design of a cage radio-frequency transmitting coil operating in an orthogonal excitation mode can meet the requirement of transmitting magnetic field uniformity within a range of human body. A body radio-frequency transmitting coil designed such is integrated into a conventional field intensity magnetic resonance system as a conventional configuration, which can meet imaging needs of any part. However, a large-aperture ultrahigh field magnetic resonance system with the field intensity of the main magnetic field greater than 3 tesla and available for human body imaging is generally not provided with the body radio-frequency transmitting coil. The large-aperture ultrahigh field magnetic resonance system available for human body imaging is different from medical magnetic resonance system with conventional field intensity, needs to consider the design of adding a radio-frequency transmitting coil while designing a radio-frequency receiving coil, and needs to add an additional circuit to avoid signal coupling between the radio-frequency transmitting coil and the radio-frequency receiving coil. At the same time, the design with both a radio-frequency transmitting coil and a radio-frequency receiving coil can also be compatible with a medical magnetic resonance system under conventional field intensity; otherwise, they are incompatible with each other. For the radio-frequency receiving coil, a multi-channel phased array radio-frequency receiving coil is widely used, which can ensure the requirement for a high SNR in a large imaging range. At the same time, the multi-channel phased array radio-frequency receiving coil can be used for accelerating image acquisition and improving image quality with a parallel imaging technology.

Functional magnetic resonance imaging methods for capturing neural activities in the brain require a special magnetic resonance radio-frequency coil assembly with high performance. A conventional magnetic resonance radio-frequency coil assembly is very sensitive to the motion of objects in an imaging process, which may introduce time-domain noise signals and becomes a key bottleneck factor restricting functional magnetic resonance imaging signal quality. For time-domain noise, when an SNR of an image is high, a main component of the time-domain noise is the fluctuation of a radio-frequency receiving coil signal caused by the displacement of a load object. When the SNR of the image is low, the main component of the time-domain noise begins to change into the fluctuation of a thermal noise level of the radio-frequency receiving coil caused by the displacement of the load object. Thermal noise sources of a radio-frequency coil include two parts: one is thermal noise caused by a conduction current inside a radio-frequency coil electronic device, and the other is thermal noise caused by a displacement current inside the load object. Since the level of the displacement current in the second part is determined by relative positions of the radio-frequency coil and the load object, it may also be affected by the displacement of the load object in the imaging process. Therefore, the radio-frequency coil with high time-domain signal stability should have two features at the same time. Firstly, a signal level of the radio-frequency coil, namely, the sensitivity is not easily affected by the displacement of the load object. Secondly, a thermal noise level of the radio-frequency coil is not easily affected by the displacement of the load object.

### SUMMARY

In view of this, an objective of embodiments of the present disclosure is to provide a magnetic resonance imaging radio-frequency coil assembly with high time-domain signal stability, which solves the problem that signal and noise characteristics of a radio-frequency coil during magnetic resonance brain imaging, especially during brain functional imaging are easily affected by the displacement of a to-be-imaged object.

The technical solution adopted by the embodiments of the present disclosure is as follows:

The embodiments of the present disclosure provide a magnetic resonance imaging radio-frequency coil assembly with high time-domain signal stability, including: a radio-frequency transmitting coil unit and a plurality of radio-frequency receiving coil units, wherein a plane area of the radio-frequency transmitting coil unit is larger than a sum of layout plane areas of all of the plurality of radio-frequency receiving coil units, the plurality of radio-frequency receiving coil units are arranged at an internal side of the radio-frequency transmitting coil unit, an overall size of an array formed by the plurality of radio-frequency receiving coil units is larger than a size of an imaging region, a circumference of each of the plurality of radio-frequency receiving coil units is less than one tenth of a wavelength of a vacuum electromagnetic wave, and a quality factor of the plurality of radio-frequency receiving coil units in a no-load state is more than 2 times a quality factor of the plurality of radio-frequency receiving coil units in a load state.

Further, the radio-frequency transmitting coil unit and the plurality of radio-frequency receiving units are directly placed inside a housing and are fixed relative to each other.

Further, a fixed device interface is provided at an external side of the housing, such that the housing has no relative displacement with respect to a to-be-imaged object.

Further, the radio-frequency transmitting coil unit and the plurality of radio-frequency receiving coil units are metal conductors.

Further, the radio-frequency transmitting coil unit and the plurality of radio-frequency receiving coil units are copper wires with insulation coating.

Further, the radio-frequency transmitting coil unit and the plurality of radio-frequency receiving coil units include a diode circuit for ensuring that the radio-frequency transmitting coil unit and the plurality of radio-frequency receiving coil units are not in an operating state simultaneously.

Further, the plurality of radio-frequency receiving coil units are connected in series with a parallel LC resonance circuit with a diode, and an operating frequency of the resonance circuit is the same as an operating frequency of the plurality of radio-frequency receiving coil units; and when the diode is forward-biased, the parallel LC resonance circuit connected in series with the plurality of radio-frequency receiving coil units is in a resonance state, and the radio-frequency transmitting coil unit is in an off-resonance state and does not operate; when the diode is backward-biased, the radio-frequency transmitting coil unit operates.

Further, the radio-frequency transmitting coil unit is connected in series with a circuit with a diode, when the diode is forward-biased, the radio-frequency transmitting coil unit is in a resonance state and operates; when the diode is backward-biased, the radio-frequency transmitting coil unit does not operate.

Further, measures are taken for achieving signal isolation among the plurality of radio-frequency receiving units, that is, signal isolation among the plurality of radio-frequency receiving coil units is achieved by geometric overlap; and the plurality of radio-frequency receiving coil units are directly connected to a pre-amplifier to reduce a coaxial-cable loss, and the plurality of radio-frequency receiving coil units and the pre-amplifier are encapsulated together at an internal side of a housing structure.

Further, the radio-frequency transmitting coil unit and the plurality of radio-frequency receiving coil units operate at a frequency of 297.2 MHz, the radio-frequency transmitting coil unit is of an annular structure, a diameter of the radio-frequency transmitting coil unit is 7 cm, and a diameter of each of the plurality of radio-frequency receiving coil units is 1.5 cm.

Compared with the prior art, the embodiments of the present disclosure have the following beneficial effects: the following three technical features are combined simultaneously, including an overall size of an array formed by the radio-frequency transmitting coil unit and the radio-frequency receiving coil units being larger than a size of an imaging region, a size of each radio-frequency receiving unit is far smaller than a wavelength of a vacuum electromagnetic wave (i.e., a circumference of each radio-frequency receiving coil unit being less than one tenth of a wavelength of a vacuum electromagnetic wave), thermal noise from the load accounting for a small proportion in the radio-frequency receiving coil units, and a quality factor of the radio-frequency receiving coil unit in a no-load state being more than 2 times that of the radio-frequency receiving coil unit in a load state. By means of the design of a housing that can interface with an external fixed device, there is no relative displacement among a radio-frequency transmitting coil, a radio-frequency receiving coil, and a to-be-imaged object, which can achieve an effect of minimizing the interference of the movement of the to-be-imaged object with the time-domain stability of an imaging signal and has a potential huge application prospect in the field of functional magnetic resonance imaging having high requirements for the time-domain stability of the signal.

### BRIEF DESCRIPTION OF DRAWINGS

In order to more clearly illustrate technical solutions described in the embodiments of the present disclosure, the accompanying drawings used in the embodiments are briefly introduced as follows. It should be noted that the drawings described as follows are merely part of the embodiments of the present disclosure, and other drawings can also be acquired by those skilled in the art according to the drawings without paying creative efforts.

FIG. 1 is a schematic diagram of layout of an array of radio-frequency receiving coils in a magnetic resonance imaging radio-frequency coil assembly with high time-domain signal stability according to an embodiment of the present disclosure, in which 1 denotes the radio-frequency receiving coil;

FIG. 2 is a schematic diagram of a connection between a radio-frequency receiving coil array and a radio-frequency pre-amplifier, in which 1 denotes the radio-frequency receiving coil and 2 denotes the radio-frequency pre-amplifier;

FIG. 3 is a schematic diagram of the layout of an array of radio-frequency receiving coils and a radio-frequency transmitting coil, in which 1 denotes the radio-frequency receiving coil, 2 denotes a radio-frequency pre-amplifier, and 3 denotes a radio-frequency transmitting coil unit;

FIG. 4 is a structural diagram of a housing of a radio-frequency coil assembly, in which 4 denotes a device interface and 5 denotes the housing;

FIG. 5 is a schematic diagram of an overall structure according to an embodiment of the present disclosure, in which 1 denotes a radio-frequency receiving coil, 2 denotes a radio-frequency pre-amplifier, 3 denotes a radio-frequency transmitting coil unit, 4 denotes a fixed device interface, and 5 denotes a housing;

FIG. 6 is a schematic diagram of a magnetic resonance imaging experiment design for studying the influence of the displacement of a load object on a radio-frequency receiving coil signal and thermal noise, in which 6 denotes a radio-frequency coil assembly including a radio-frequency transmitting coil unit and radio-frequency receiving coil units, 7 denotes a Teflon pad, and 8 denotes a cylindrical liquid model (whose conductivity and dielectric constant close to those of human tissue);

FIG. 7 shows comparison results of the influence of the displacement of a load object on a thermal noise level of different types of radio-frequency receiving coils;

FIG. 8 shows comparison results of time-domain fluctuation of thermal noise levels of radio-frequency receiving coils with different quality factor ratios under no load/load in the presence of the displacement of a load object; and

FIG. 9 is a diagram of comparison results of signal time-domain fluctuation amplitudes of radio-frequency receiving coils with different diameters in the presence of the displacement of a load object.

### DESCRIPTION OF EMBODIMENTS

To make the objectives, technical solutions, and advantages of this application clearer, the following clearly and completely describes the technical solutions of this application with reference to specific embodiments of this application and the corresponding accompanying drawings. Apparently, the described embodiments are merely part of rather than all of the embodiments of this application. All other embodiments obtained by those of ordinary skill in the art without creative efforts based on the embodiments of this application are within the protection scope of this application.

The quality factor ratio under no load/load mentioned in the specification refers specifically to a ratio of a quality factor of a radio-frequency receiving coil unit in a no-load state to a quality factor of the radio-frequency receiving coil unit in a load state.

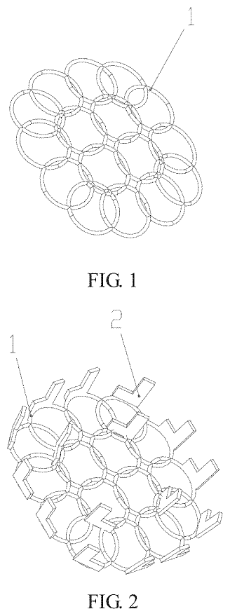

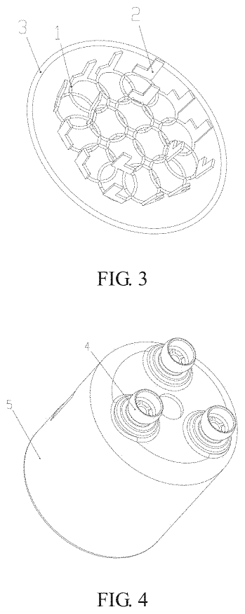

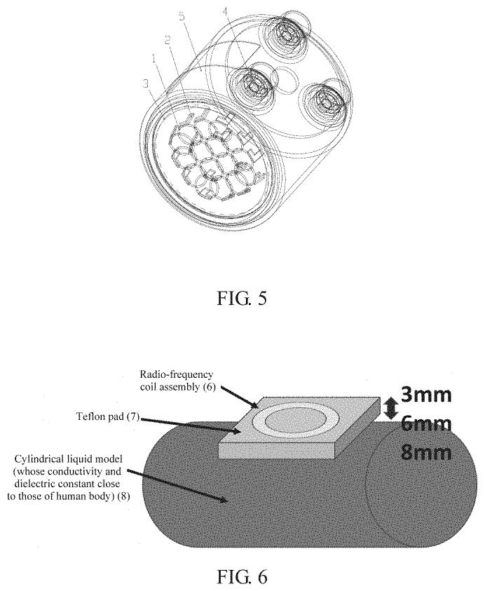

As shown in FIG. 1 to FIG. 5, an embodiment of the present disclosure provides a magnetic resonance imaging radio-frequency coil assembly with high time-domain signal stability, mainly including a single-channel radio-frequency transmitting coil unit 3 and a plurality of radio-frequency receiving coil units 1. All the radio-frequency receiving coil units 1 are arranged into an array on a circular plane (i.e., the plurality of radio-frequency receiving coil units 1 are arranged in the form of a circular array). The receiving coil units 1 overlap each other, and signal isolation between the radio-frequency receiving coils is enhanced by mutual inductance. A central axis of the radio-frequency transmitting coil 3 is coincident with a central axis of a circular plane where the array of the radio-frequency receiving coils 1 is located, with a coverage range greater than a sum of coverage ranges of all the radio-frequency receiving coils 1. The array of the radio-frequency receiving coils is compatible with a parallel imaging function of a magnetic resonance imaging system, which helps to shorten the scanning time and improve the image quality. The radio-frequency receiving coils are connected in series with a capacitor and then is connected to respective pre-amplifiers 2. The capacitor is used for impedance matching and enhancement of the decoupling performance between radio-frequency coil channels.

The single-channel radio-frequency transmitting coil 3 is used to match the electromagnetic load of the to-be-imaged object, so as to achieve high transmission efficiency and uniform excitation of a brain range.

A further technical solution is to obtain a ratio of a quality factor of the radio-frequency receiving coil unit in a no-load state to a quality factor of the radio-frequency receiving coil unit in a load state through a radio-frequency network analyzer test. The quality factor of the radio-frequency receiving coil unit in the no-load state is more than 2 times that of the radio-frequency receiving coil unit in the load state. In an embodiment, each radio-frequency receiving coil 1 is a circular structure with an effective diameter of 1.5 cm, and the array of the plurality of radio-frequency receiving coils 1 is arranged with an effective coverage diameter of 7 cm.

A further technical solution is that a resonant frequency of the radio-frequency coil shown in the embodiment is equal to 297.2 MHz, which can be used in a magnetic resonance system with the field intensity of the main magnetic field greater than or equal to 7 tesla and in a magnetic resonance system without a body transmitting coil.

The pre-amplifiers 2 are directly connected to the radio-frequency receiving coils 1, which reduces the space occupied by the coil through integrated design to facilitate the fixation with the to-be-imaged object, that is, to maintain no relative displacement, while avoiding a coaxial-cable loss and improving an imaging SNR.

An overlap range of geometric overlap of the radio-frequency receiving coils 1 is determined by an overlap range measured by a network analyzer when a forward transmission coefficient S21 between channels is less than −15 dB. The radio-frequency transmitting coil unit 3 and the radio-frequency receiving coil units 1 may be copper wires with insulation coating.

Three fixed device interfaces 4 are mounted to a radio-frequency coil housing 5, which can facilitate the fixation with an external fixed device, so as to be used for mechanical fixing in the process of magnetic resonance imaging, to ensure that there is no relative displacement between the radio-frequency transmitting coil, the radio-frequency receiving coils, and the to-be-imaged object.

The working principle of the magnetic resonance imaging radio-frequency coil assembly with high time-domain signal stability according to the present disclosure is as follows:

Based on experimental measurement data, a larger effective coverage range of a radio-frequency coil indicates that a signal is less affected by the object-coil displacement. A smaller size of a single radio-frequency receiving unit indicates a smaller ratio of a quality factor under no load to a quality factor under load. That is, a smaller ratio of thermal noise from the load to an overall thermal noise level indicates that the thermal noise level is less affected by the object-coil displacement. A large-scale high-density radio-frequency receiving coil array composed of small-sized radio-frequency receiving coil units is proposed, which has a large signal coverage range. The object-coil displacement during magnetic resonance imaging can be further minimized from the source through the design of a housing that can interface with an external fixed device. Thus, an overall effect can achieve high time-domain signal stability.

FIG. 6 is a schematic diagram of a magnetic resonance imaging experiment design for studying the influence of the displacement of a load object on a radio-frequency receiving coil signal and thermal noise. In the experimental design, a cylindrical liquid model 8, which has conductivity and dielectric constant close to those of human tissue, is used as the load object. In an experiment, a Teflon pad 7 with different thicknesses (3 mm, 6 mm, 8 mm) is placed between a radio-frequency coil and the load object to simulate the influence of the displacement of the load object on the radio-frequency coil signal and thermal noise characteristics. A dielectric constant of the Teflon pad 7 is close to a vacuum dielectric constant. In a case that the Teflon pad 7 with each thickness is used, 60 imaging samples are taken in 2 minutes for a signal level and a thermal noise level of a radio-frequency coil 6, so as to acquire time-domain fluctuation data and variance of the radio-frequency receiving coil signal and thermal noise in the absence of the displacement of the load object. When a Teflon pad 7 with different thicknesses is used, acquired signal and thermal noise time-domain fluctuation data is randomly mixed to obtain simulated data under the displacement of the load object. Four types of radio-frequency coils 6 with different sizes and quality factor ratios under no load/load are used in the experiment, including: the radio-frequency coil according to the embodiment of the present disclosure, an annular radio-frequency coil with a diameter of 2 cm having both receiving and transmitting functions, an annular radio-frequency coil with a diameter of 3.5 cm having both receiving and transmitting functions, and an annular radio-frequency coil with a diameter of 5 cm having both receiving and transmitting functions. The radio-frequency coil according to the embodiment of the present disclosure used in the experiment and three other annular radio-frequency coils having both receiving and transmitting functions are equipped with different types of pre-amplifiers. All experiments are carried out on a 7-T ultra-high field large-aperture human magnetic resonance system.

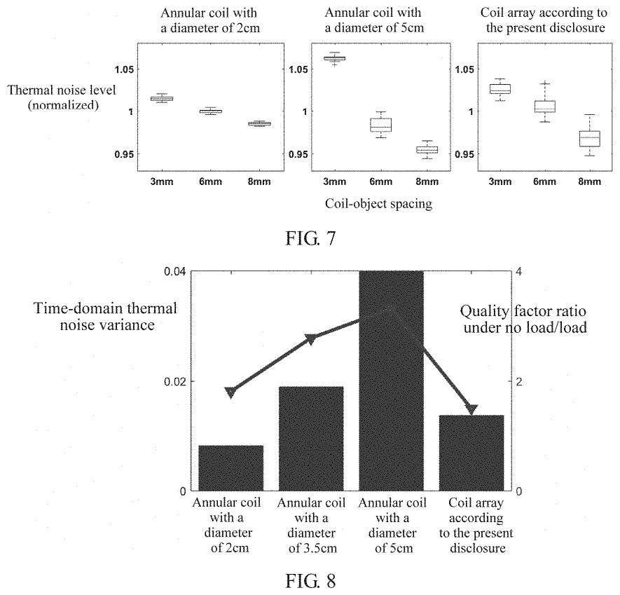

FIG. 7 shows comparison results of thermal noise fluctuation amplitudes of radio-frequency receiving coils. Data is from a 7-T ultra-high field magnetic resonance water model imaging experiment, and thermal noise is obtained by turning off radio-frequency excitation energy acquisition. The figure shows that the radio-frequency coil array according to the embodiment of the present disclosure has a minimum thermal noise fluctuation, embodied in the minimum inter-group variance, followed by the annular radio-frequency coil with a diameter of 2 cm having both receiving and transmitting functions, and finally the annular radio-frequency coil with a diameter of 5 cm having both receiving and transmitting functions. At the same time, the size of the radio-frequency receiving unit of the radio-frequency coil array according to the embodiment of the present disclosure is the smallest, followed by the annular radio-frequency coil with a diameter of 2 cm having both receiving and transmitting functions, and finally the annular radio-frequency coil with a diameter of 5 cm having both receiving and transmitting functions. According to the consensus in the field of magnetic resonance radio-frequency coils, the smaller a physical size of a radio-frequency receiving coil unit is, the smaller the contribution made by the thermal noise from the load is, that is, the smaller a quality factor ratio of the radio-frequency receiving unit under no load/load is. Therefore, a conclusion can be reached that the contribution made by the thermal noise from the load is smaller, that is, the thermal noise level of the radio-frequency receiving coil unit with a smaller quality factor ratio under no load/load is insensitive to the load displacement.

FIG. 8 shows results of time-domain thermal noise variance of various radio-frequency receiving coils and ratios of quality factors of the radio-frequency receiving units under no load/load. It can be seen that the time-domain noise variance of the radio-frequency receiving coils is correlated with the ratios of the quality factors of the radio-frequency receiving units under no load/load. Therefore, a conclusion can be reached that the contribution made by the thermal noise from the load is smaller, that is, the thermal noise level of the radio-frequency receiving coil unit with a smaller quality factor ratio under no load/load is insensitive to the load displacement. Finally, differences in types of radio-frequency pre-amplifiers used in various radio-frequency receiving coils need to be discussed, that is, the use of different radio-frequency pre-amplifiers between the radio-frequency coil according to the present embodiment and other radio-frequency coils may potentially lead to deviations in data correlation.

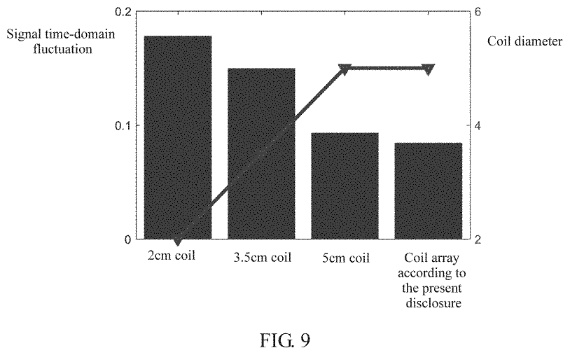

FIG. 9 shows comparison results of quality factors of radio-frequency receiving units when various radio-frequency receiving coil signal time-domain fluctuations are under no load/load. The radio-frequency receiving coil array according to the embodiment of the present disclosure has a maximum coverage range, followed by the annular radio-frequency coil with a diameter of 5 cm having both receiving and transmitting functions and the annular radio-frequency coil with a diameter of 3.5 cm having both receiving and transmitting functions, and finally the annular radio-frequency coil with a diameter of 2 cm having both receiving and transmitting functions. It can be seen from the results in the figure that the radio-frequency coil with a larger radio-frequency receiving coil coverage range has a smaller signal time-domain fluctuation. Although the radio-frequency receiving coil array according to the embodiment of the present disclosure is formed by radio-frequency receiving coil units of the smallest size, an overall radio-frequency receiving coil formed by a plurality of radio-frequency receiving coil unit arrays has a maximum effective coverage range, which still shows the smallest signal time-domain fluctuation. Thus, a conclusion can be reached that a signal level of the radio-frequency receiving coil with a smaller radio-frequency receiving coil coverage range is less sensitive to the load displacement.

The above are merely preferred embodiments of the present disclosure, but are not intended to limit the patent scope of the present disclosure. Any equivalent structure transformation made by using the specification and the content of the drawings of the present disclosure, or direct or indirect applications to other related technical field should be included in the patent protection scope of the present disclosure.

What is claimed is:

1. A magnetic resonance imaging radio-frequency coil assembly with high time-domain signal stability, comprising: a radio-frequency transmitting coil unit and a plurality of radio-frequency receiving coil units, wherein a plane area of the radio-frequency transmitting coil unit is larger than a sum of layout plane areas of all of the plurality of radio-frequency receiving coil units, the plurality of radio-frequency receiving coil units are arranged at an internal side of the radio-frequency transmitting coil unit, an overall size of an array formed by the plurality of radio-frequency receiving coil units is larger than a size of an imaging region, a circumference of each of the plurality of radio-frequency receiving coil units is less than one tenth of a wavelength of a vacuum electromagnetic wave, and a quality factor of the plurality of radio-frequency receiving coil units in a no-load state is more than 2 times a quality factor of the plurality of radio-frequency receiving coil units in a load state.

2. The magnetic resonance imaging radio-frequency coil assembly with high time-domain signal stability according to claim 1, wherein the radio-frequency transmitting coil unit and the plurality of radio-frequency receiving units are directly placed inside a housing and are fixed relative to each other.

3. The magnetic resonance imaging radio-frequency coil assembly with high time-domain signal stability according to claim 2, wherein a fixed device interface is provided at an external side of the housing, such that the housing has no relative displacement with respect to a to-be-imaged object.

4. The magnetic resonance imaging radio-frequency coil assembly with high time-domain signal stability according to claim 1, wherein the radio-frequency transmitting coil unit and the plurality of radio-frequency receiving coil units are metal conductors.

5. The magnetic resonance imaging radio-frequency coil assembly with high time-domain signal stability according to claim 4, wherein the radio-frequency transmitting coil unit and the plurality of radio-frequency receiving coil units are copper wires with insulation coating.

6. The magnetic resonance imaging radio-frequency coil assembly with high time-domain signal stability according to claim 1, wherein the radio-frequency transmitting coil unit and the plurality of radio-frequency receiving coil units comprise a diode circuit for ensuring that the radio-frequency transmitting coil unit and the plurality of radio-frequency receiving coil units are not in an operating state simultaneously.

7. The magnetic resonance imaging radio-frequency coil assembly with high time-domain signal stability according to claim 6, wherein the plurality of radio-frequency receiving coil units are connected in series with a parallel LC resonance circuit with a diode, and an operating frequency of the resonance circuit is the same as an operating frequency of the plurality of radio-frequency receiving coil units; and when the diode is forward-biased, the parallel LC resonance circuit connected in series with the plurality of radio-frequency receiving coil units is in a resonance state, and the radio-frequency transmitting coil unit is in an off-resonance state and does not operate; when the diode is backward-biased, the radio-frequency transmitting coil unit operates.

8. The magnetic resonance imaging radio-frequency coil assembly with high time-domain signal stability according to claim 6, wherein the radio-frequency transmitting coil unit is connected in series with a circuit with a diode, when the diode is forward-biased, the radio-frequency transmitting coil unit is in a resonance state and operates; when the diode is backward-biased, the radio-frequency transmitting coil unit does not operate.

9. The magnetic resonance imaging radio-frequency coil assembly with high time-domain signal stability according to claim 1, wherein signal isolation among the plurality of radio-frequency receiving coil units is achieved by geometric overlap; and the plurality of radio-frequency receiving coil units are directly connected to a pre-amplifier to reduce a coaxial-cable loss, and the plurality of radio-frequency receiving coil units and the pre-amplifier are encapsulated together at an internal side of a housing structure.

10. The magnetic resonance imaging radio-frequency coil assembly with high time-domain signal stability according to claim 1, wherein the radio-frequency transmitting coil unit and the plurality of radio-frequency receiving coil units operate at a frequency of 297.2 MHz, the radio-frequency transmitting coil unit is of an annular structure, a diameter of the radio-frequency transmitting coil unit is 7 cm, and a diameter of each of the plurality of radio-frequency receiving coil units is 1.5 cm.
